(19) United States
(12) Patent Application Publication
(10) Pub. No.: US 2026/0005207 A1
(43) Pub. Date: Jan. 1, 2026

(54) SEMICONDUCTOR PACKAGE WITH ADIABATIC WELL STRUCTURE

(71) Applicant: Taiwan semiconductor Manufacturing Co., Ltd., Hsinchu (TW)

(72) Inventors: Chiahung Liu, Hsinchu (TW); Ming-Fa Chen, Taichung (TW); Chih-Huang Li, Taichung (TW); Tsung-Yu Chen, Hsinchu (TW); Lipu Kris Chuang, Hsinchu (TW)

(21) Appl. No.: 18/916,111

(22) Filed: Oct. 15, 2024

Related U.S. Application Data
(60) Provisional application No. 63/665,334, filed on Jun. 28, 2024.

(51) Int. Cl. H01L 25/16; H01L 21/48; H01L 23/00; H01L 23/528; H01L 23/58; H10B 80/00

(52) U.S. Cl. CPC H01L 25/16; H01L 21/4853; H01L 23/5283; H01L 24/16; H01L 23/585; H01L 24/08; H01L 24/13; H01L 24/32; H01L 24/73; H01L 24/80; H01L 2224/08145; H01L 2224/13147; H01L 2224/13157; H01L 2224/13184; H01L 2224/16; H01L 2224/32225; H01L 2224/73204; H01L 2224/80895; H01L 2224/80896; H01L 2924/351; H10B 80/00

(57) ABSTRACT

In an embodiment, a semiconductor package may include a photonic integrated circuit (PIC) die having a wavelength modulator and a heating element thermally coupled to the wavelength modulator. The semiconductor package may also include an interconnect structure on the PIC die, where the interconnect structure may include a plurality of conductive features and a void. The void overlaps with the heating element and the wavelength modulator from a top view. The package may furthermore include a plurality of conductive connectors over the interconnect structure and electrically connected to the plurality of conductive features.

### PRIORITY CLAIM AND CROSS-REFERENCE

This application claims the benefit of U.S. Provisional Application No. 63/665,334, filed on Jun. 28, 2024, which application is hereby incorporated herein by reference.

### BACKGROUND

Electrical signaling and processing are one of techniques for signal transmission and processing. Optical signaling and processing have been used in increasingly more applications in recent years, particularly due to the use of optical fiber-related applications for signal transmission.

Optical signaling and processing are typically combined with electrical signaling and processing to provide full-fledged applications. For example, optical fibers may be used for long-range signal transmission, and electrical signals may be used for short-range signal transmission as well as processing and controlling. Accordingly, devices integrating optical components and electrical components are formed for the conversion between optical signals and electrical signals, as well as the processing of optical signals and electrical signals. Packages thus may include both optical (photonic) dies including optical devices and electronic dies including electronic devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 6B illustrate the formation of a photonic integrated circuit (PIC) die at various stages of processing, according to some embodiments.

FIGS. 7A through 10 illustrate cross-sectional views of semiconductor package structures with different configurations of adiabatic wells and thermal isolation features, according to some embodiments.

FIGS. 11 through 19 illustrate the formation of a PIC die at various stages of processing, according to some embodiments.

FIGS. 20 through 31 illustrate cross-sectional views of semiconductor package structures integrating photonic and electronic components with thermal management features, according to some embodiments.

FIGS. 32 and 33 illustrate cross-sectional views of semiconductor package structures integrating photonic and electronic components with thermal management features, according to some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The semiconductor industry has been advancing, with devices becoming smaller, faster, and more complex. One area of growth is silicon photonics, which integrates optical components with traditional electronic circuits. This integration allows for faster data transmission and processing, which may be beneficial for applications in telecommunications, data centers, and high-performance computing. As these devices become more sophisticated, they face challenges in managing heat.

Heat management can be important in silicon photonics devices due to the presence of sensitive optical components such as wavelength modulators. These modulators may require precise temperature control to function effectively. Traditional heat dissipation methods, which may work well for purely electronic devices, may not be as effective when applied to integrated photonic and electronic systems. Excessive heat can lead to performance issues, reduced lifespan of components, and device malfunction.

The present disclosure describes a thermal management approach through a packaging design. This design includes a photonic integrated circuit (PIC) die that contains a wavelength modulator and a heating element. The heating element is thermally coupled to the modulator, which may allow for temperature control. The PIC die is integrated into the overall package structure in a specific manner.

The package includes an interconnect structure on top of the PIC die. This interconnect structure contains conductive features for electrical connections and a void area. This void area or metal-free region, also referred to as an “adiabatic well,” is positioned to overlap with the heating element and wavelength modulator when viewed from above. The void may form a thermal barrier, isolating the heat-sensitive components from the rest of the package.

To enhance the thermal management capabilities, the package may include additional features such as a Thermal Isolation Bump (TIB) and an intra-die seal ring. These structures may work together with the adiabatic well to provide thermal isolation. The TIB may surround the adiabatic well, creating a buffer zone to limit heat spread to other parts of the package. The intra-die seal ring may help to contain degradation of passivation materials that could occur due to heat exposure.

The disclosed embodiments offer several advantages over current alternatives in the prior art. The adiabatic well structure provides superior heat insulation compared to conventional copper spreader solutions, effectively preventing overheating of polyimide and underfill materials. By reducing the risk of polyimide delamination, the present disclosure enhances the overall reliability and longevity of silicon photonics packages. Unlike copper spreaders that can degrade heater efficiency by up to 26%, this disclosure allows for independent control of the heater for the micro ring modulator without interference from heat dissipation structures. The disclosed embodiments eliminate the need for extra lithography processes to define patterns, potentially reducing production costs and complexity. The adiabatic well, thermal isolation bump, and substrate drilling opening can be implemented in various shapes (circular, rectangular, triangular, etc.) to suit different package designs. The combination of these elements provides a multi-faceted approach to thermal management, addressing heat-related issues more effectively than existing solutions. The present disclosure allows for effective thermal management without compromising the performance of the micro ring modulator or other silicon photonics components. Finally, the design principles can be applied to various sizes and configurations of silicon photonics packages, making it adaptable to different product requirements.

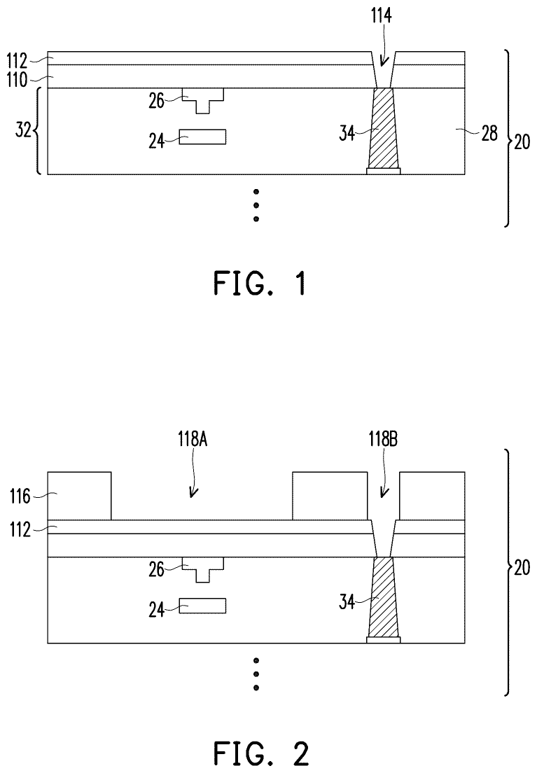

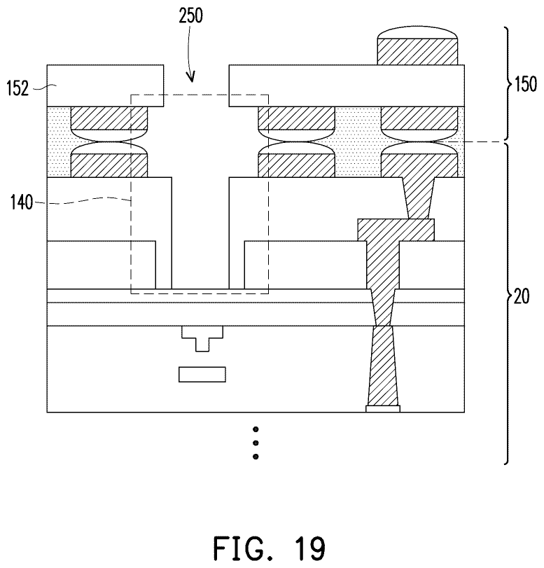

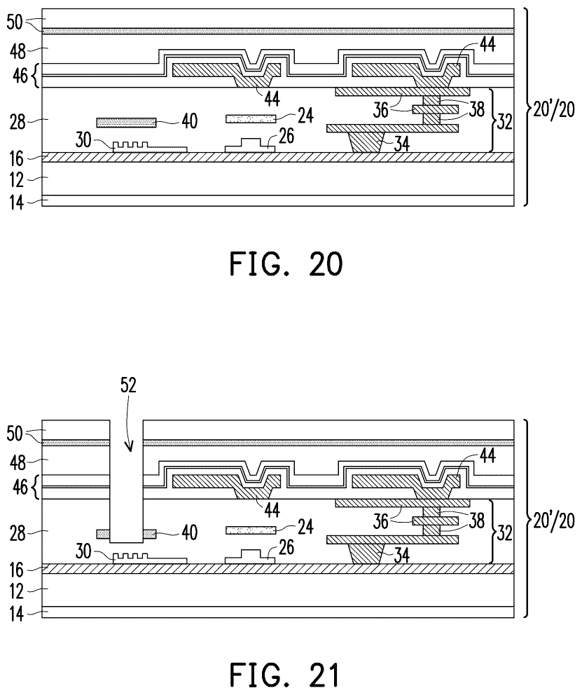

FIGS. 1 through 6B illustrate the formation of a photonic die at various stages of processing, according to some embodiments. Referring to FIG. 1, a cross-sectional view of a portion of a photonic integrated circuit (PIC) die 20 (may be referred to as a photonic die 20) at an intermediate stage of processing is illustrated. The photonic die 20 is part of a semiconductor package structure designed for thermal management in silicon photonics devices. The other portions of the photonic die 20 will be discussed in FIGS. 20-31.

The portion of the photonic die 20 shown in FIG. 1 includes an interconnect structure 32. The interconnect structure 32 may comprise a plurality of conductive features, such as metal lines and vias, that facilitate electrical connections within the device. The interconnect structure 32 may include one or more dielectric layers 28, a heater 24, and a micro-ring modulator 26. The heater 24 provides thermal energy for the operation of the micro-ring modulator 26. The micro-ring modulator 26 and the heater 24 are thermally coupled, allowing for precise temperature control of the micro-ring modulator 26.

The one or more dielectric layers 28 may include silicon oxide, silicon oxynitride, aluminum oxide, aluminum nitride, or the like. A metal via 34 extends from the interconnect structure 32 upwards through the one or more dielectric layers 28. The metal via 34 provides an electrical connection between the interconnect structure 32 and other components or layers of the device. The metal via 34 may be formed through a single damascene process by forming an opening in the dielectric layers 28, and filling the openings with conductive materials. The conductive materials may include a diffusion barrier layer formed of TiN, TaN, Ti, Ta, or the like, and a metallic material such as tungsten, copper, cobalt, or the like. A planarization process such as a CMP process or a mechanical grinding process may be performed to remove excess conductive material. The remaining portions of the diffusion barrier layer and the metallic material forms the via 34.

A dielectric layer 110 is formed on the one or more dielectric layers 28. The dielectric layer 110 may be an oxide layer or other suitable dielectric material. A buffer layer is formed on the dielectric layer 110. The buffer layer 112 may be a single layer or multiple layers. For example, the buffer layer 112 may be a stacked layer of silicon nitride, bismuth silicate, and silicon nitride.

An opening 114 is formed through the buffer layer 112 and dielectric layer 110, aligned with the metal via 34. This opening 114 extends from the top surface of the buffer layer 112 down to the dielectric layer 28. The opening 114 may be formed by any suitable etching or patterning process.

The structure shown in FIG. 1 represents a portion of the photonic die 20, illustrating the arrangement of various components involved in the thermal management and optical modulation functions of the device. The specific configuration of these components, including the heater 24, the micro-ring modulator 26, and the interconnect structure 32, may vary depending on the specific design and performance requirements of the photonic die 20.

Referring to FIG. 2, a passivation layer 116 is formed and patterned over the buffer layer 112. The passivation layer 116 may be composed of an organic dielectric material, which may be a polymer such as polyimide, polybenzoxazole (PBO), benzocyclobutene (BCB), or the like. The passivation layer 116 serves to protect the underlying layers and components from environmental factors, such as moisture and contaminants.

The passivation layer 116 is patterned to form two openings: a well opening 118A and a redistribution layer (RDL) opening 118B. The well opening 118A is a larger cavity positioned above the heater 24 and the micro-ring modulator 26. This opening is designed to create an air gap or “adiabatic well” in subsequent processing steps, which may serve as a thermal barrier to isolate these heat-sensitive components from the rest of the package.

Adjacent to the well opening 118A, the RDL opening 118B is a narrower opening. This opening is designed to facilitate the formation of a redistribution layer in subsequent processing steps. The redistribution layer may include conductive features that provide electrical connections between various components and layers of the device.

The patterning of the passivation layer 116 to form the well opening 118A and the RDL opening 118B may be achieved through any suitable process. For example, photolithography and etching techniques may be used to selectively remove portions of the passivation layer 116, creating the openings. The specific dimensions and shapes of these openings may vary depending on the design and performance requirements of the photonic die 20. In some cases, the well opening 118A and the RDL opening 118B may be formed simultaneously in a single patterning step.

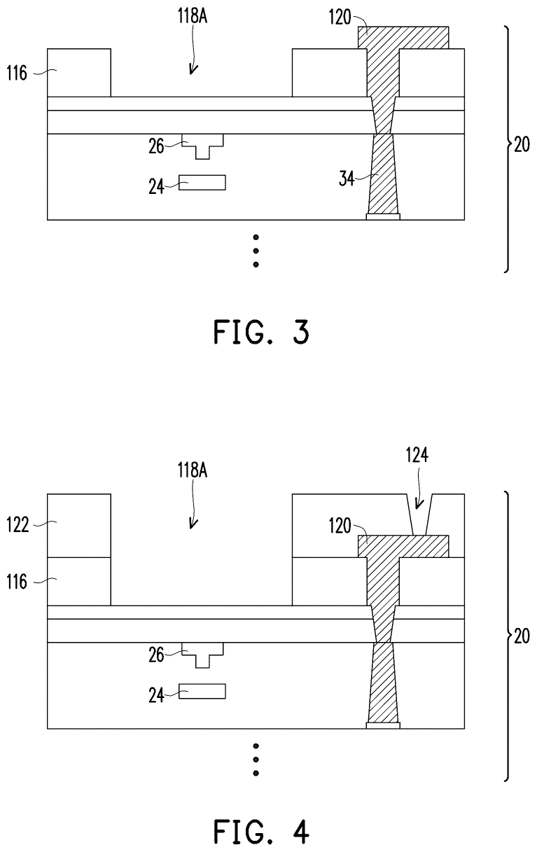

Referring to FIG. 3, a cross-sectional view of the photonic die 20 at a subsequent stage of processing is illustrated. In this stage, a redistribution layer 120 is formed in the RDL opening 118B. The redistribution layer 120 extends from the top surface of the passivation layer 116 down to the dielectric layer 28, connecting to the metal via 34. The redistribution layer 120 may be composed of a conductive material, and may be formed by any suitable process, such as deposition and patterning. For example, 120 the conductive materials forming the redistribution layer may include a diffusion barrier layer formed of TiN, TaN, Ti, Ta, or the like, and a metallic material such as tungsten, copper, cobalt, or the like. The redistribution layer 120 serves to provide electrical connections between various components and layers of the device.

The formation of the redistribution layer 120 in the RDL opening 118B results in a structure where the redistribution layer 120 and the well opening 118A are adjacent to each other within the passivation layer 116. This configuration may allow for the simultaneous management of electrical connectivity and thermal isolation within the photonic die 20. The redistribution layer 120 provides electrical paths for the operation of the device, while the well opening 118A, which remains as an air gap, may serve as a thermal barrier to isolate the heat-sensitive components, such as the heater 24 and the micro-ring modulator 26, from the rest of the package.

The interconnect structure 32 may include a void or metal-free region, which is the area of the structure that does not contain any conductive features. In the context of the present disclosure, the well opening 118A may be considered as part of this metal-free region. The absence of conductive material in this region contributes to its function as a thermal barrier, as it reduces the potential for heat conduction through the interconnect structure 32. In some embodiments, the metal-free region overlaps with the heating element 24 and the wavelength modulator 26 when viewed from above. This arrangement may ensure that the heat generated by these components is effectively isolated, improving the thermal management of the device.

Referring to FIG. 4, a second passivation layer 122 is formed and patterned over the first passivation layer 116 and the redistribution layer 120. The second passivation layer 122 may be composed of similar materials as the first passivation layer 116, such as an organic dielectric material. The formation of the second passivation layer 122 may involve deposition processes, and the patterning may be achieved through photolithography and etching techniques, or other suitable methods.

The second passivation layer 122 is patterned to form a connector opening 124 and to extend the well opening 118A. The connector opening 124 is designed to expose a portion of the redistribution layer 120, facilitating the formation of electrical connectors in subsequent processing steps. The specific dimensions and shapes of the connector opening 124 and the extended well opening 118A may vary depending on the design and performance requirements of the photonic die 20.

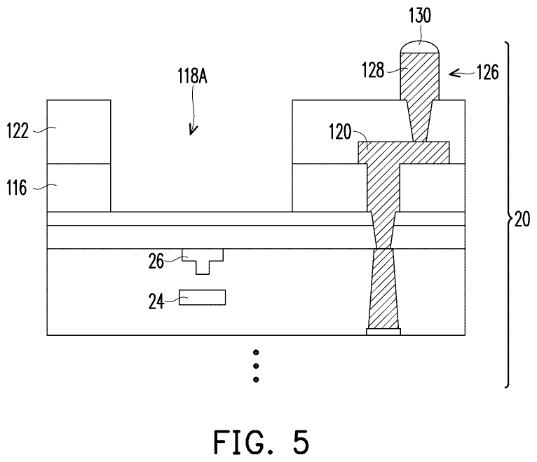

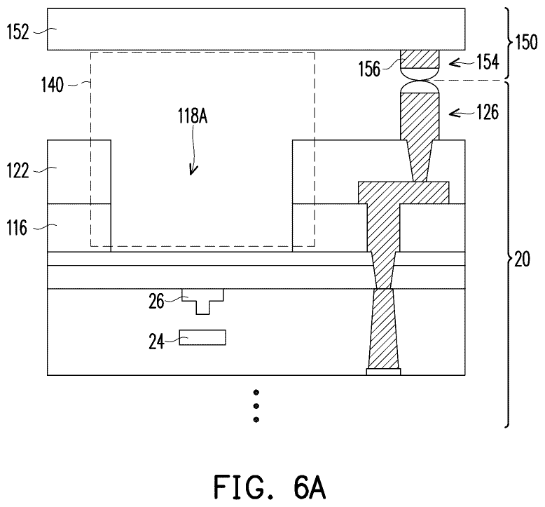

Referring to FIG. 5, an electrical connector 126 is formed in the connector opening 124. The electrical connector 126 extends from the top surface of the passivation layer 122 down to the redistribution layer 120, establishing an electrical connection between these layers. The electrical connector 126 may be composed of a conductive material and may be formed by any suitable process, such as deposition and patterning. The conductive materials may be similar to the redistribution layer 120 discussed above. The electrical connector 126 includes a metal pillar 128 and a solder region 130. The metal pillar 128 provides a conductive path for the electrical connector 126, while the solder region 130 facilitates the bonding of the electrical connector 126 to other components or layers of the device.

The formation of the electrical connector 126 in the connector opening 124 results in a structure where the electrical connector 126 and the well opening 118A are adjacent to each other within the passivation layer 122. This configuration may allow for the simultaneous management of electrical connectivity and thermal isolation within the photonic die 20. The electrical connector 126 provides the necessary electrical paths for the operation of the device, while the well opening 118A, which remains as an air gap, may serve as a thermal barrier to isolate the heat-sensitive components, such as the heater 24 and the micro-ring modulator 26, from the rest of the package.

In some embodiments, the electrical connector 126 may be part of a plurality of conductive connectors over the redistribution layer 120. These conductive connectors may be electrically connected to the conductive features of the redistribution layer 120, facilitating the routing of electrical signals within the device. The specific layout and configuration of these conductive connectors may vary depending on the design and performance requirements of the photonic die 20.

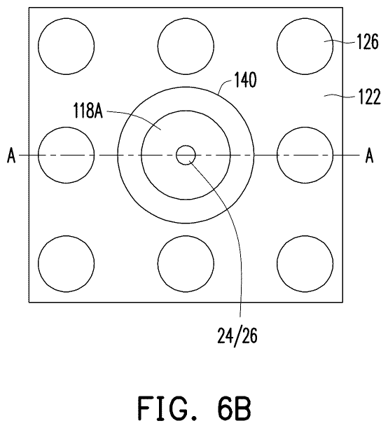

FIGS. 6A and 6B illustrate the photonic die 20 bonded to a substrate package 150. FIG. 6A is a cross-sectional view and FIG. 6B is a top view with FIG. 6A being along the line A-A in FIG. 6B.

The substrate package 150 includes a substrate 152, which may be a package substrate, semiconductor substrate, or the like. The bonding of the substrate package 150 to the photonic die 20 may be achieved through a solder reflow process or other suitable bonding processes.

The bonding process results in the formation of an adiabatic well 140. The adiabatic well 140 corresponds to the well opening 118A, which was previously formed in the passivation layers 116 and 122. The adiabatic well 140 extends from the top surface of the buffer layer 112 to the bottom surface of the substrate 152. In some aspects, the adiabatic well 140 may be filled with air, forming an air gap that serves as a thermal insulation layer.

The formation of the adiabatic well 140 provides an advantage in terms of thermal management. The air gap within the adiabatic well 140 acts as a thermal barrier, effectively isolating the heat generated by the heater 24 and the micro-ring modulator 26 from the rest of the package. This thermal isolation may help to prevent overheating of the photonic die 20 and the substrate package 150, enhancing the reliability and performance of the device.

In some embodiments, the adiabatic well 140 may be formed by removing specific layers over the heater 24 and the micro-ring modulator 26. These layers may include passivation materials, redistribution layers, and other components that are typically present in the photonic die 20. The removal of these layers may create a void or air gap (or metal-free region) in the structure, which serves as the adiabatic well 140.

Referring to FIG. 6B, the well opening 118A, which forms part of the adiabatic well 140, is shown as a circular region in the center of the structure. The well opening 118A is aligned with the heater 24 and the micro-ring modulator 26, which are the heat-generating components of the photonic die 20. This alignment ensures that the heat generated by these components is effectively isolated within the adiabatic well 140. Surrounding the well opening 118A is the adiabatic well 140, depicted as a larger circular region.

In some embodiments, the well opening 118A, the adiabatic well 140, and the electrical connectors 126 may be formed in various shapes, such as circular, rectangular, or triangular, depending on the specific design and performance requirements of the photonic die 20. The flexibility in the design of these features may allow for the customization of the package structure to suit different applications and device configurations.

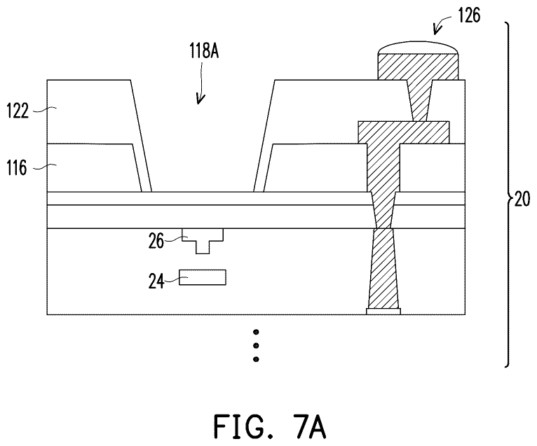

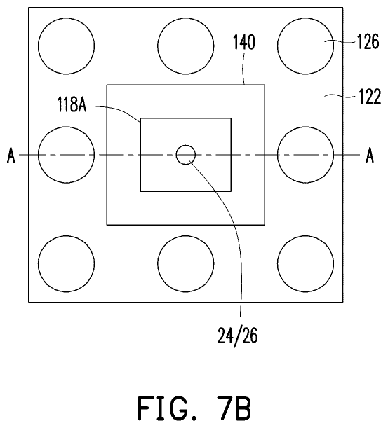

FIGS. 7A and 7B illustrate another embodiment of the photonic die 20.

FIG. 7A is a cross-sectional view and FIG. 7B is a top view with FIG. 7A being along the line A-A in FIG. 7B. This embodiment is similar to the embodiment illustrated in FIGS. 1 through 6B. Details regarding this embodiment that are similar to those for the previously described embodiment will not be repeated herein.

In this embodiment, the well opening 118A in the passivation layer 116 is formed with a tapered or cone shape. This tapered shape may provide certain advantages in terms of thermal management, as it may help to direct heat away from the heater 24 and the micro-ring modulator 26, enhancing the thermal isolation capabilities of the adiabatic well.

In some aspects, the tapered shape of the well opening 118A may be achieved through a specific etching or patterning process. For example, an anisotropic etching process may be used to create the tapered profile of the well opening 118A. The specific parameters of the etching process, such as the etching rate and the etching time, may be adjusted to control the shape and dimensions of the well opening 118A.

In this embodiment, the second passivation layer 122 is formed to cover the opening of the first passivation layer 116. This arrangement may help to prevent moisture from getting into the interface between the first passivation layer 116 and the second passivation layer 122. The prevention of moisture ingress may be beneficial for the reliability and performance of the photonic die 20, as moisture can cause degradation of the passivation layers and other components of the device.

The structure shown in FIG. 7A represents an alternative configuration of the adiabatic well in the photonic die 20. This configuration illustrates how variations in the shape and arrangement of the well opening 118A and the passivation layers 116 and 122 can influence the thermal management capabilities of the device.

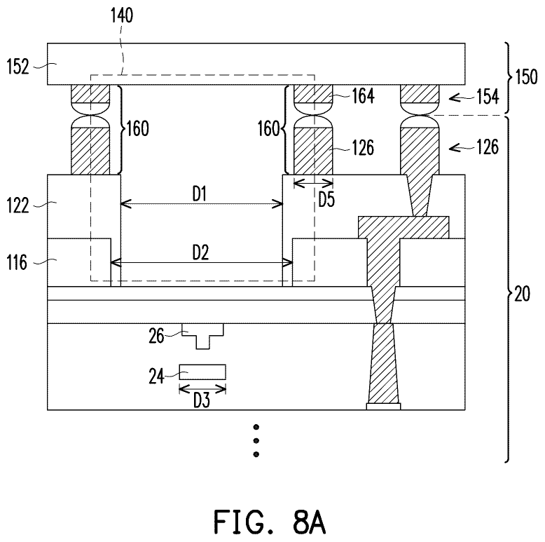

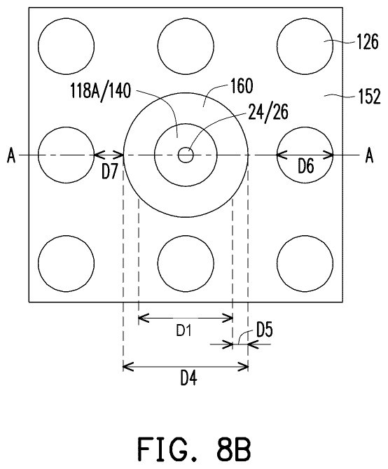

FIGS. 8A and 8B illustrate another embodiment of the photonic die 20 bonded to the substrate package 150. FIG. 8A is a cross-sectional view and FIG. 8B is a top view with FIG. 8A being along the line A-A in FIG. 8B. This embodiment is similar to the embodiment illustrated in FIGS. 1 through 6B. Details regarding this embodiment that are similar to those for the previously described embodiment will not be repeated herein.

In this embodiment, the photonic die 20 includes a thermal isolation structure, specifically a thermal isolation bump (TIB) 160, surrounding the adiabatic well 140. The TIB 160 may serve to contain the air within the adiabatic well 140 and provide a thermal buffer between the adiabatic well 140 and surrounding areas.

The TIB 160 includes TIB connectors 162 and 164, which may be formed at the same time and by similar processes as the electrical connectors 126. The TIB connectors 162 and 164 may be composed of a conductive material and may be formed by any suitable process, such as deposition and patterning. The conductive materials may be similar to the redistribution layer 120 discussed above. The TIB connectors 162 and 164 serve as a thermal buffer to limit heat spread to other parts of the package.

The TIB 160 use several principles to provide thermal isolation. Firstly, the TIB 160 act to contain the air within the adiabatic well 140. This containment of air can help maintain the thermal isolation properties of the air gap. Secondly, the metal in the TIB 160 has thermal mass, which means it requires energy to heat up. This property can act as a buffer, slowing the transfer of heat from the well to the surrounding areas. Thirdly, while metal is generally a good conductor of heat, the specific geometry and arrangement of the TIB 160 may create a longer path for heat to travel compared to direct conduction through a solid material. This longer path can reduce the rate of heat transfer, contributing to the thermal isolation function of the TIB 160. Fourthly, by sealing the air gap, the TIB 160 may reduce convection currents that could otherwise transfer heat more efficiently. Lastly, depending on the metal used, the TIB 160 might reflect some thermal radiation back into the well, further contributing to isolation.

The figure also indicates several distances for the structure's design. The width of the adiabatic well 140 at the level of passivation layer 122, represented by D1, may range from 42 to 85 micrometers. D2, which is the distance between sidewalls of the passivation layer 116, may range from 62 to 105 micrometers. The width of the heater 24, denoted by D3, may be approximately 4 micrometers. The width of the TIB 160 structure, represented by D5, may range from 20 to 70 micrometers. Additionally, the difference between D2 and D1 may be approximately 10 micrometers. These dimensions may vary depending on the specific design and performance requirements of the photonic die 20, allowing for customization of the package structure to suit different applications and device configurations.

Referring to FIG. 8B, a top view of the semiconductor package structure is illustrated. The figure also indicates several distances for the structure's design. In some embodiments, width of the adiabatic well 140 at the level of passivation layer 122, represented by D1, may be either 30 or 50 micrometers. In these embodiment, the overall width of the TIB structure 160, represented by D4, may range from 70 to 170 micrometers if D1 is 30 micrometers, or from 90 to 190 micrometers if D1 is 50 micrometers. The width of an electrical connector 126, denoted by D6, may be approximately 90 micrometers. The distance between the TIB 160 and an electrical connector 126, represented by D7, may range from 20 to 70 micrometers if D1 is 30 micrometers, or from 10 to 60 micrometers if D1 is 50 micrometers. These dimensions may vary depending on the specific design and performance requirements of the photonic die 20, allowing for customization of the package structure to suit different applications and device configurations.

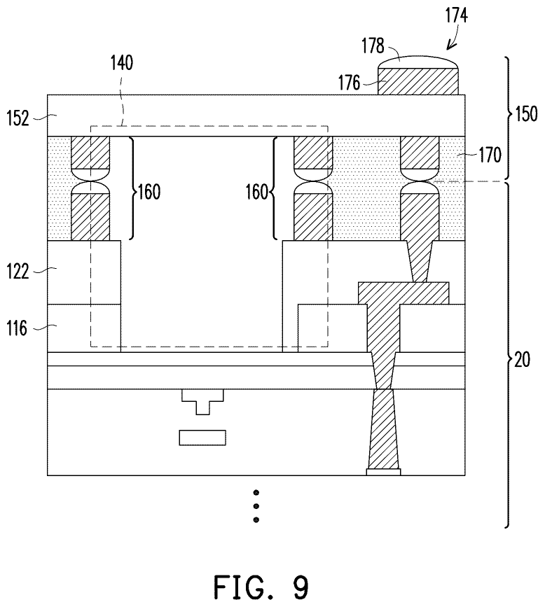

FIG. 9 illustrates a package structure, in accordance with some embodiments. This embodiment is similar to the embodiment illustrated in FIGS. 8A and 8B. Details regarding this embodiment that are similar to those for the previously described embodiment will not be repeated herein.

In this embodiment an underfill material 170 is formed between the photonic die 20 and the substrate package 150 and an electrical connector 174 is formed on the substrate package 150. The underfill material 170 is present in the spaces between the electrical connectors 126 and other components, providing structural support and assisting with heat dissipation. The underfill material 170 may be composed of a thermally conductive material, such as a thermally conductive epoxy or other suitable material. The underfill material 170 may be applied in a liquid or semi-liquid state, filling the spaces between the components, and then cured or hardened to form a solid structure. The underfill material 170 may help to enhance the mechanical stability of the package, reducing the risk of component displacement or damage due to mechanical stress or thermal expansion.

The electrical connector 174 may be similar to the electrical connectors 126 and 154, and may be formed by similar processes. The electrical connector 174 includes a metal pillar 176 and a solder region 178, facilitating electrical connection between the substrate package 150 and an external structure.

The addition of the underfill material 170 and the electrical connector 174 in this embodiment may provide several benefits. The underfill material 170 may enhance the mechanical stability of the package, improving the reliability and longevity of the device. The electrical connector 174 may provide an additional electrical connection point, enhancing the electrical connectivity of the package. These features, in combination with the thermal management capabilities of the adiabatic well 140 and the TIB 160, may contribute to the overall performance and reliability of the semiconductor package.

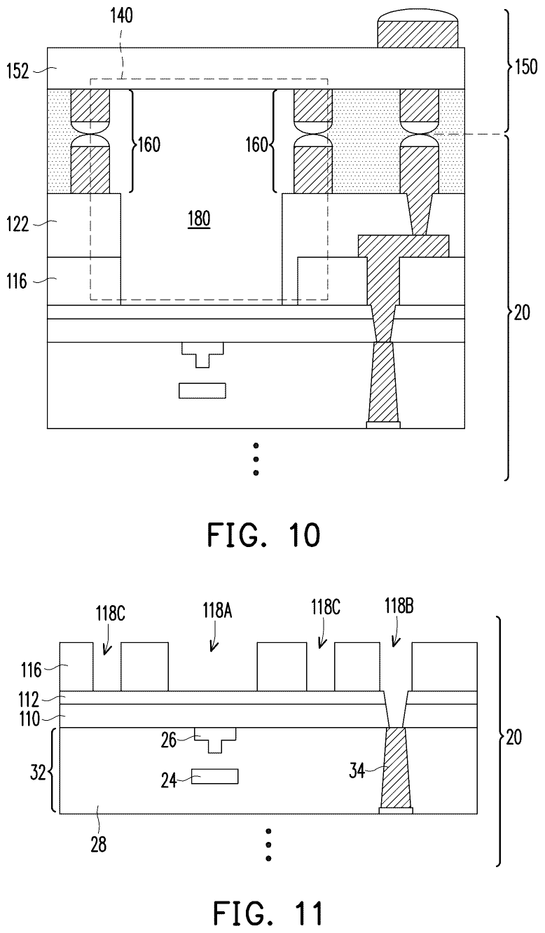

FIG. 10 illustrates a package structure in accordance with some embodiments. This embodiment is similar to the embodiment illustrated in FIG. 9. Details regarding this embodiment that are similar to those for the previously described embodiment will not be repeated herein.

In this embodiment, the adiabatic well 140 is filled with a thermal resist material 180. The thermal resist material 180 may serve as a thermal insulation layer, enhancing the thermal isolation capabilities of the adiabatic well 140.

The thermal resist material 180 may be composed of a material with low thermal conductivity, such as a gas or a foam. In some cases, the thermal resist material 180 may be a gas, such as carbon dioxide, which has a thermal conductivity of 0.015 W/M·K. In other cases, the thermal resist material 180 may be a foam, such as urethane foam, which has a thermal conductivity of 0.026 W/M·K. The specific type and properties of the thermal resist material 180 may vary depending on the design and performance requirements of the photonic die 20.

The thermal resist material 180 may be introduced into the adiabatic well 140 through a filling process. This process may involve injecting the thermal resist material 180 into the adiabatic well 140 in a liquid or gaseous state, and then allowing it to solidify or stabilize within the well. The filling process may be controlled to ensure that the thermal resist material 180 fully fills the adiabatic well 140, maximizing the thermal isolation effect.

The introduction of the thermal resist material 180 into the adiabatic well 140 may provide several benefits. The thermal resist material 180 may enhance the thermal isolation capabilities of the adiabatic well 140, reducing the transfer of heat from the heater 24 and the micro-ring modulator 26 to other parts of the package. This may help to prevent overheating of the photonic die 20 and the substrate package 150, enhancing the reliability and performance of the device. Furthermore, the use of a thermal resist material 180 may provide a more stable and durable thermal barrier compared to an air gap, improving the longevity of the thermal management solution.

In some embodiments, the adiabatic well 140 filled with the thermal resist material 180 may be surrounded by a thermal isolation structure, such as the TIB 160. The TIB 160 may serve to contain the thermal resist material 180 within the adiabatic well 140 and provide a thermal buffer between the adiabatic well 140 and surrounding areas.

FIGS. 11 through 17 illustrate the formation of a photonic die at various stages of processing, according to some embodiments. This embodiment is similar to the embodiment illustrated in FIGS. 1 through 5 and 8A and 8B. Details regarding this embodiment that are similar to those for the previously described embodiment will not be repeated herein.

Referring to FIG. 11, a cross-sectional view of the photonic die 20 at an intermediate stage of processing is illustrated. In this stage, the passivation layer 116 is patterned to form several openings. The openings include the well opening 118A, redistribution layer (RDL) opening 118B, and seal ring openings 118C. In some embodiments, the RDL openings 118B and seal ring openings 118C are smaller than the well opening 118A.

Referring to FIG. 12, a mask 210 is formed and patterned over the passivation layer 116. The mask 210 serves to define areas for the formation of redistribution layers and seal ring structures in subsequent processing steps. The mask 210 is patterned to cover the well opening 118A and expose RDL opening 118B and the seal ring openings 118C.

The mask 210 may be composed of a photosensitive material, such as a photoresist, which can be selectively exposed and developed to create the desired pattern. The formation of the mask 210 may involve a coating process, such as spin coating or spray coating, to deposit a uniform layer of the mask material over the passivation layer 116. The patterning of the mask 210 may be achieved through a photolithography process, which involves exposing the mask 210 to light through a photomask with the desired pattern, and then developing the exposed mask 210 to remove the exposed or unexposed regions, depending on the type of photoresist used.

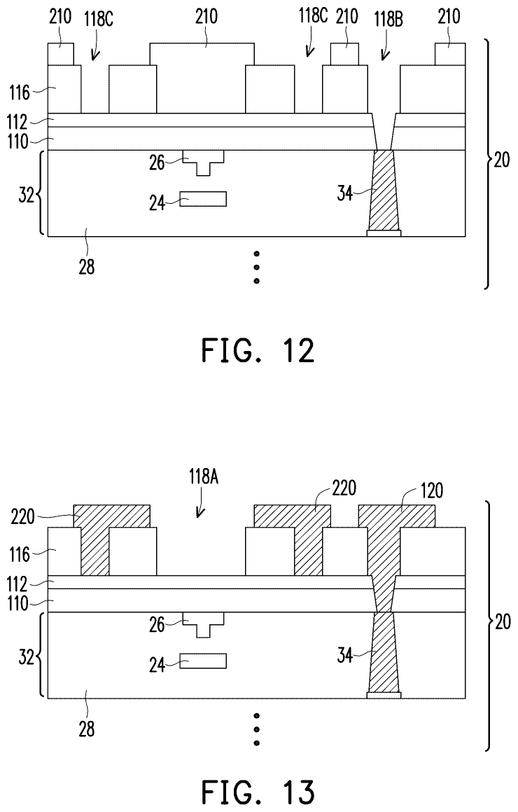

Referring to FIG. 13, the RDL 120 and a seal ring RDL 220 are formed on the photonic die 20. The RDL 120 and the seal ring RDLs 220 are formed in the RDL opening 118B and the seal ring openings 118C, respectively, which were previously patterned in the passivation layer 116. The RDL 120 and the seal ring RDL 220 may be composed of a conductive material and may be formed by any suitable process, such as deposition and patterning. The conductive materials may be similar to the redistribution layer 120 discussed above.

The seal ring RDL 220 is formed surrounding the well opening 118A. The seal ring RDL 220 may serve to contain degradation of passivation materials that could occur due to heat or liquid exposure.

After the formation of the redistribution layer 120 and the seal ring RDL 220, the mask 210 may be removed by any suitable process, such as ashing, a lift-off process or a stripping process. The removal of the mask 210 may be achieved through any suitable process, such as a lift-off process or a stripping process. The specific method used for the removal of the mask 210 may depend on the material of the mask 210 and the requirements of the subsequent processing steps. The removal of the mask 210 exposed the well opening 118A.

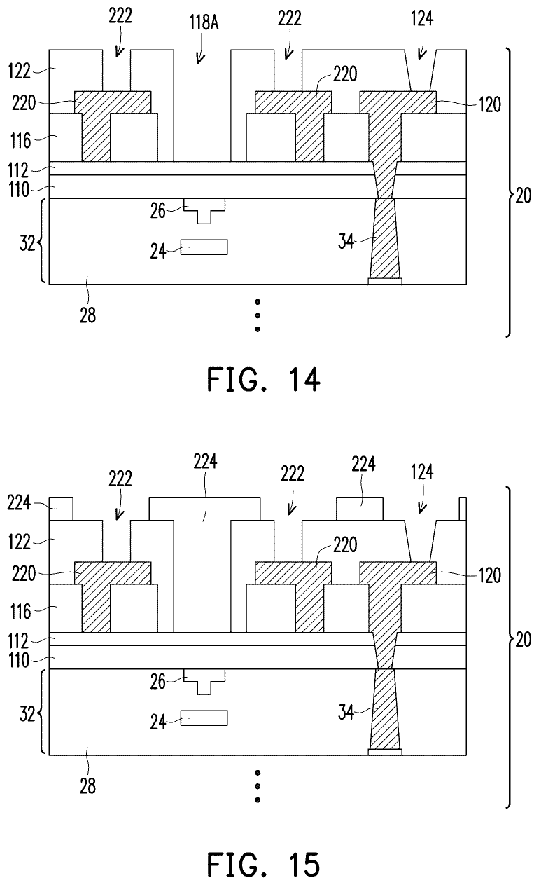

Referring to FIG. 14, the second passivation layer 122 is formed and patterned over the first passivation layer 116, the seal ring RDL 220, and the RDL 120. In addition to extending the well opening 118A and the connector opening 124, the second passivation layer 122 is also patterned to form openings 222 to expose portions of the seal ring RDL 220. These openings 222 may facilitate the formation of seal ring connectors in subsequent processing steps.

Referring to FIG. 15, a mask 224 is formed and patterned over the second passivation layer 122. The mask 224 serves to define areas for the formation of redistribution layers and seal ring structures in subsequent processing steps. The mask 224 is patterned to cover the well opening 118A and expose the seal ring openings 222 and the connector opening 124. The mask 224 may be similar to the mask 210 and the description is not repeated herein.

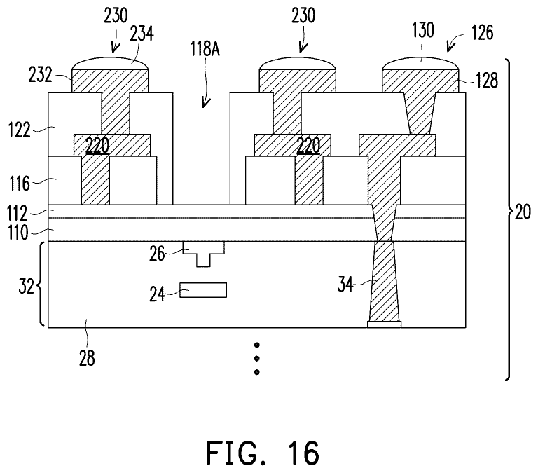

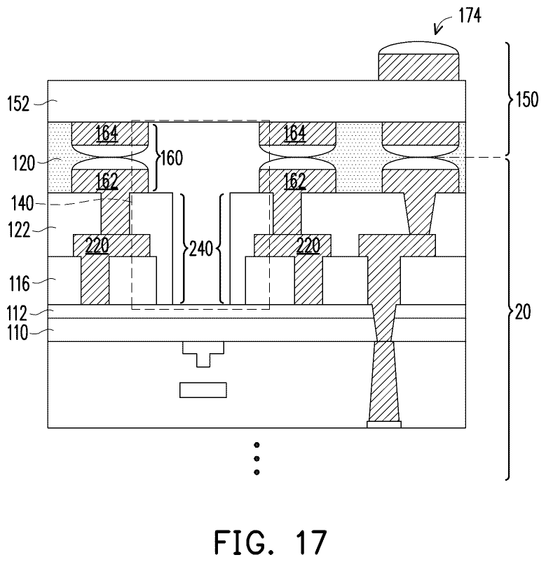

Referring to FIG. 16, the electrical connector 126 and seal ring connectors 230 are formed on the photonic die 20. The electrical connector 126 is formed in the connector opening 124. In addition to the electrical connector 126, seal ring connectors 230 are also formed on the photonic die 20. The seal ring connectors 230 are formed surrounding the well opening 118A and are coupled to the seal ring RDL 220. The seal ring connectors 230 include a seal ring pillar 232 and a seal ring solder region 234, which may be formed at the same time and by similar processes as the electrical connector 126. The seal ring connectors 230 may be considered a dummy connected as they are not electrically coupled to circuitry and they serve as a barrier or seal ring to limit the degradation of passivation materials. The portions of the seal ring connectors 230 above the top surface of the second passivation layer 122 may be considered a thermal isolation bump (TIB) and serve the same purpose as TIB 160 while the portion of the seal ring RDLS 220 and the seal ring connector 230 within the first and second passivation layers 116 and 122 form a seal ring structure 240 (see FIG. 17).

Referring to FIG. 17, the photonic die 20 is bonded to the substrate package 150 and underfill material 170 is formed. This embodiment includes the TIB 160 and a seal ring structure 240. The seal ring structure 240 includes the seal ring RDL 220 and portions of the seal ring connectors 230 in the passivation layers 116 and 122 and is designed to surround the adiabatic well 140. The seal ring structure 240 may help to prevent moisture from getting through the passivation layers 116 and 122 into or out of the adiabatic well 140. This may be beneficial in environments with high humidity or in applications where the device is exposed to moisture.

The integration of the TIB 160 and the seal ring structure 240 in this embodiment provides a comprehensive approach to thermal management in the photonic die 20. The TIB 160 and the seal ring structure 240 work together with the adiabatic well 140 to provide thermal isolation, contain passivation material degradation, and prevent moisture intrusion. This may enhance the reliability and performance of the device, extending its lifespan and improving its operational efficiency.

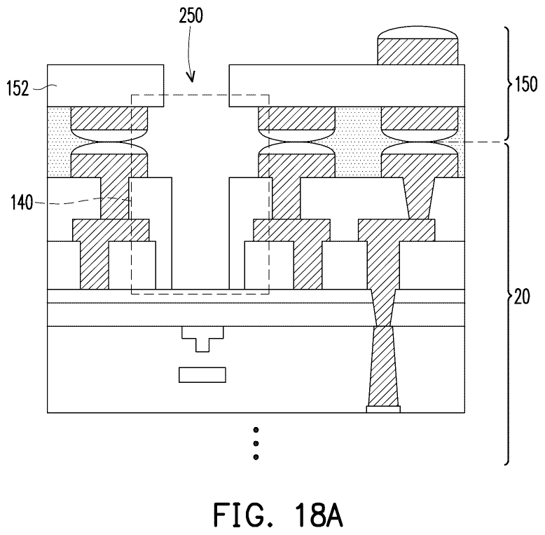

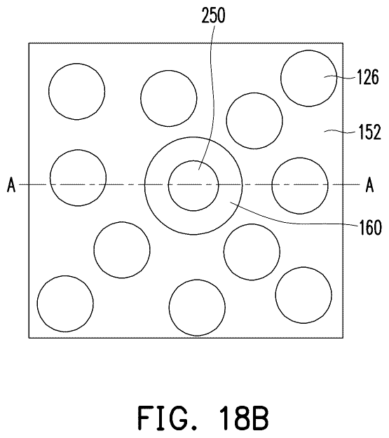

FIGS. 18A and 18B is illustrate a package structure in accordance with some embodiments. FIG. 18A is a cross-sectional view and FIG. 18B is a top view with FIG. 18A being along the line A-A in FIG. 18B. This embodiment is similar to the embodiment illustrated in FIGS. 11 through 17. Details regarding this embodiment that are similar to those for the previously described embodiment will not be repeated herein.

In this embodiment, a substrate opening 250 is formed in the substrate package 150. The substrate opening 250 is aligned with the adiabatic well 140, enhancing the thermal isolation capabilities of the adiabatic well 140. The substrate opening 250 may be formed by any suitable process, such as drilling or etching, and may be filled with air or another thermal resist material.

The introduction of the substrate opening 250 provides an advantage in terms of thermal management, effectively allowing the heat generated by the heater 24 and the micro-ring modulator 26 to be removed and not affect the rest of the package. This may help to prevent overheating of the photonic die 20s and the substrate package 150.

The substrate opening 250 may be filled with a thermal resist material, such as a gas or a foam, to further enhance the thermal isolation capabilities of the adiabatic well 140. The specific type and properties of the thermal resist material may vary depending on the design and performance requirements of the photonic die 20s.

In some embodiments, he well opening 118A, the adiabatic well 140, the TIB 160, and the electrical connectors 126 may be formed in various shapes, such as circular, rectangular, or triangular, depending on the specific design and performance requirements of the photonic die 20s. The flexibility in the design of these features may allow for the customization of the package structure to suit different applications and device configurations.

FIG. 19 illustrates a package structure in accordance with some embodiments. This embodiment is similar to the embodiment illustrated in FIGS. 18A and 18B. Details regarding this embodiment that are similar to those for the previously described embodiment will not be repeated herein.

In this embodiment, the substrate opening 250 is present but the seal ring structure 240 is not.

FIGS. 20 through 31 illustrate the views of intermediate stages in the formation of a package including a photonic die in accordance with some embodiments, in which a photonic die 20 of FIGS. 1 through 19 are adopted.

Referring to FIG. 20, a photonic die 20′ is formed. In some embodiments, the photonic die 20′ is a part of an unsawed photonic wafer 20, which includes a plurality of photonic dies 20′ that are identical. The photonic die 20′ may also be referred to as a PIC 20′.

The photonic die 20′ may include a semiconductor substrate 12, which may be a silicon substrate in accordance with some embodiments. There may be, or may not be, a dielectric layer 14 underneath the semiconductor substrate 12. A dielectric layer 16 is formed over the semiconductor substrate 12. In some embodiments, the dielectric layer 16 is an etch stop layer that is used in the subsequent formation of conductive features. The material of the dielectric layer 16 may comprise silicon nitride, silicon oxynitride, silicon carbide, silicon oxycarbide, silicon oxide, or the like.

In some embodiments, the photonic die 20′ may include integrated circuit devices (not shown) formed at a surface of the semiconductor substrate 12. The integrated circuit devices (if formed) are used to support the functionality of the photonic die in accordance with some embodiments. The integrated circuit devices may include active devices such as transistors and/or diodes. The integrated circuit devices may also include passive devices such as capacitors, resistors, or the like. In some embodiments, no integrated circuit devices are formed in the photonic die 20′.

The photonic die 20′ may include photonic devices such as waveguides, grating couplers, modulators, and/or the like. The waveguides may include silicon waveguides and/or silicon nitride waveguides. In some embodiments, dielectric layers 28 are formed, and may include silicon oxide, silicon oxynitride, aluminum oxide, aluminum nitride, or the like.

In some embodiments, the photonic devices may include a grating coupler 30, which may be formed of silicon in accordance with some embodiments. For example, a silicon layer may be formed on the dielectric layer 16, for example, by bonding the silicon layer to the dielectric layer 16, followed by the patterning of the silicon layer through etching, so that waveguides, grating couplers, and the like are formed. In some embodiments, adjacent to the grating coupler 30 are a heater 24 and a micro-ring modulator 26.

In some embodiments, dielectric layers 28 are formed over the grating coupler 30. The dielectric layers 28 may comprise light-transparent and low-loss dielectric materials such as silicon oxide. In some embodiments, the dielectric layers underlying an etch stop layer 40 (if formed) may include silicon oxide. The dielectric materials over the etch stop layer may include a plurality of dielectric layers formed of different materials. The plurality of dielectric layers may include Inter-Metal Dielectric (IMDs), which may include a low-k dielectric material(s) such as porous silicon oxynitride. There may also be etch stop layers formed between the low-k dielectric materials. The etch stop layer may comprise AlN, AlO, SiON, or the like, or multi-layers thereof. It is appreciated that the formation of multiple layers using different materials will not cause insertion loss since these materials will be removed from the light path.

The interconnect structure 32 is formed, which may include the metal via 34, vias 36, and metal lines 38 and the respective portions of dielectric layers 28. In some embodiments, the metal via 34 has a bottom surface contacting the dielectric layer 16. The metal via 34 may be formed through a damascene process such as a single damascene process. The vias 36 and the metal lines 38 may be formed through single damascene processes and/or dual damascene processes.

For example, the via 34, the vias 36, and the metal lines 38 may be formed through a single damascene process by forming openings in the dielectric layers 28, and filling the openings with conductive materials. The conductive materials may include a diffusion barrier layer formed of TiN, TaN, Ti, Ta, or the like, and a metallic material such as tungsten, copper, cobalt, or the like. A planarization process such as a CMP process or a mechanical grinding process may be performed to remove excess conductive material. The remaining portions of the diffusion barrier layer and the metallic material form the vias 34 and 36 and the metal lines 38.

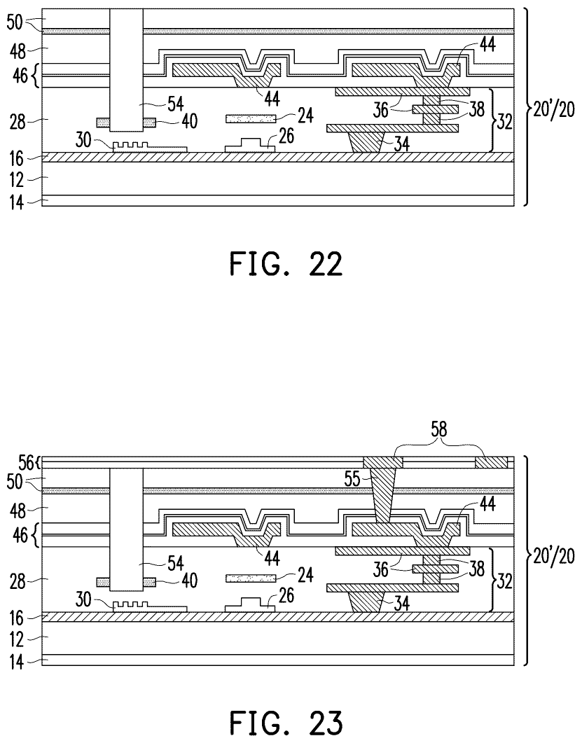

In some embodiments, an etch stop layer 40 is formed directly over the grating coupler 30 and inside the dielectric layers 28. In some embodiments, the etch stop layer 40 is not formed. The material of the etch stop layer 40 is different from the subsequently refilled dielectric region (FIG. 22). For example, the etch stop layer 40 may be formed of or comprise silicon nitride, silicon oxynitride, silicon carbide, silicon oxycarbide, or the like, or may comprise a metal-containing material such as a metal oxide (aluminum oxide, for example). In some embodiments, the formation of the etch stop layer 40 may include depositing a dielectric layer, and patterning the dielectric layer to remove some portions of the etch stop layer, leaving the portion of the etch stop layer directly over the grating coupler 30 unremoved.

In some embodiments, metal pads 44 are formed over and electrically connected to the interconnect structure 32. The metal pads 44 may be formed of aluminum copper, copper, nickel, or the like, or multi-layers thereof. Passivation layers 46 are formed over the metal pads 44. In some embodiments, the formation of the metal pads 44 may comprise depositing one of the passivation layers 46, forming openings in the passivation layer to expose the underlying metal pad in the interconnect structure 32, depositing a metal seed layer, forming a plating mask, plating a metal layer, and performing an etching process to remove exposed portions of the metal seed layer. The remaining portions of the metal layer form the metal pads 44. Each of the passivation layers 46 may have a single-layer structure or a multi-layer structure. For example, a passivation layer 46 may include a plurality of silicon oxide layers and a plurality of silicon nitride layers formed alternatingly.

A plurality of dielectric layers 48 and 50 are then formed. In some embodiments, the dielectric layer 48 may comprise an inorganic dielectric material such as silicon oxide, silicon nitride, silicon carbide, silicon oxynitride, or the like. The corresponding dielectric layer 48 may be formed through a deposition process, followed by a planarization process such as a Chemical Mechanical Polish (CMP) process or a mechanical grinding process. Alternatively, the dielectric layer 48 may be formed of or comprise an organic dielectric material, which may be a polymer such as polyimide, polybenzoxazole (PBO), benzocyclobutene (BCB), or the like. The corresponding process may include dispensing a polymer in a flowable form, and curing the polymer as a solid, followed by a planarization process. The dielectric layers 50 may also include silicon oxide, silicon nitride, silicon carbide, silicon oxynitride, or the like, and may also include etch stop layers. The top surface dielectric layer 50 may be planar, for example, formed by deposition and planarization.

FIG. 21 illustrates an etching process to form an opening 52, which penetrates through a plurality of dielectric layers in the photonic die 20′. In some embodiments, an etching mask (not shown) such as a photoresist is formed and patterned. The plurality of dielectric layers in the photonic die 20′ are etched, forming the opening 52. In some embodiments in which the etch stop layer 40 is formed, the etching process stops on the etch stop layer 40, followed by etching through the etch stop layer 40 to reveal the underlying dielectric layer 28. In some embodiments in which the etch stop layer 40 is not formed, a time mode etching process is adopted to ensure that the etching process stops when the opening 52 has a desirable depth.

In some embodiments, the etching process is stopped when the dielectric layer(s) 28 underlying the opening 52 (and thus between the opening 52 and the grating coupler 30) are all formed of a same (homogeneous material) such as silicon oxide. This may ensure the insertion loss of optical signal is minimized.

Referring to FIG. 22, the opening 52 is filled with a light-transparent dielectric material. A dielectric region 54 is thus formed. In some embodiments, the dielectric region 54 comprises silicon oxide. In some embodiments, the dielectric region 54 may comprise other dielectric materials such as silicon oxynitride. The elements other than silicon and oxygen may be low, for example, with the atomic percentage lower than 10 percent or 5 percent. The formation process may include depositing a dielectric layer to fully fill the opening 52, and performing a planarization process such as a CMP process or a mechanical grinding process to remove excess portions of the dielectric layer.

Referring to FIG. 23, a conductive via 55 is formed. The conductive via 55 may comprise a conductive material such as copper, tungsten, or the like, and may or may not include a diffusion barrier formed of Ti, TiN, Ta, TaN, or the like, or multi-layers. The conductive via 55 may land on the metal pad 44 in accordance with some embodiments.

Referring to FIG. 23, a bond layer 56 is formed. In some embodiments, the bond layer 56 may have a multi-layer structure or a single layer structure. The material of the bond layer 56 may be the same as that of the dielectric region 54. For example, the bond layer 56 may comprise silicon oxide. When formed of the same material, the bond layer 56 may be formed using atomic layer deposition (ALD), chemical vapor deposition (CVD), or the like. The bond layer 56, when having the multi-layer structure, may have sub-layers having slightly different compositions. For example, one of the dielectric layers 56 may comprise silicon oxide, and the other may comprise silicon oxynitride. Alternatively, both of the dielectric layers 56 may comprise silicon oxynitride, but have oxygen atomic percentages different from each other.

Bond pads 58 are formed in the dielectric layers 56. In some embodiments, the bond pads 58 may comprise copper, and may comprise a diffusion barrier, such as Ti, TiN, Ta, TaN, or the like. The formation process may include etching the bond layer 56 to form openings, depositing a conductive material to fill the openings, and performing a planarization process to remove the portions of the conductive material over the bond layer 56.

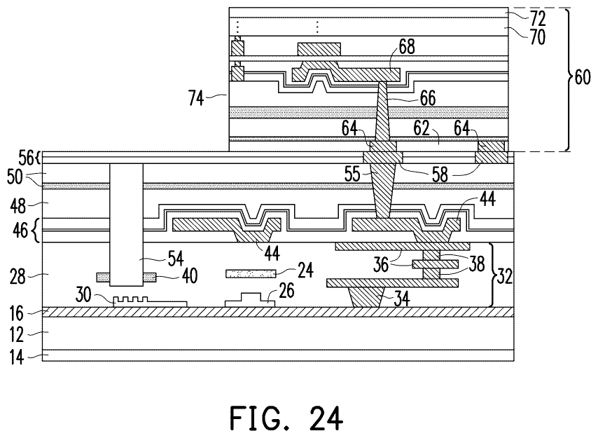

Referring to FIG. 24, another device die 60, which may be an electronic integrated circuit (EIC) die 60 (also referred to as an electronic die) or another type of die such as an independent passive device die, an integrated voltage regulator (IVR) die, or the like is bonded to the photonic die 20′. Throughout the description, the die 60 is referred to as an EIC die 60.

The EIC die 60 may include a metal pad 68, a via 66 connected to the metal pad 68, and a bond pad 64 electrically connected to the via 66. The metal pad 68 may be electrically connected to the integrated circuits in the EIC die 60. In some embodiments, the EIC die 60 includes a semiconductor substrate 70 (which may be a silicon substrate) and the integrated circuits formed on a surface of the semiconductor substrate 70. A dielectric layer 72 may be formed on the semiconductor substrate 70. The integrated circuits include active devices such as transistors. These transistors may comprise gates formed on the semiconductor substrate 70, with gate spacers adjacent to the gates. Source/drain regions may be formed in the semiconductor substrate 70 on opposite sides of each gate. Contacts may be formed to electrically connect to the gates and source/drain regions. The EIC die 60 may also include an interlayer dielectric (ILD) surrounding the gates, gate spacers, and contacts. An etch stop layer may be formed over the ILD and the contacts to facilitate the formation of subsequent layers. Additional metal interconnect layers and corresponding dielectric layers may be formed above the etch stop layer to create the interconnect structure of the EIC die 60. The EIC die 60 further includes a dielectric layer 62 as a bond layer, with bond pads 64 being formed in the bond layer 62.

The bonding between the photonic die 20′ and the EIC die 60 may include metal-to-metal direct bonding, solder bonding, or hybrid bonding that includes both of metal-to-metal direct bonding and fusion bonding. For example, the bond layer 62 is bonded to the bond layer 56 through fusion bonding. In some embodiments, the material of the bond layer 62 is different from the material of the bond layer 56, so that heterogeneous bonding may be achieved to improve the bonding strength.

In some embodiments, the EIC die 60 may include integrated circuits (not shown) for communicating with the photonic die 20′, such as the circuits for controlling the operation of the photonic die 20′. For example, the EIC die 60 may include controllers, drivers, amplifiers, the like, or combinations thereof. The EIC die 60 may also include a CPU. In some embodiments, the EIC die 60 includes the circuits for processing electrical signals received from the photonic die 20′. The EIC die 60 may also control high-frequency signaling of the photonic die 20′ according to electrical signals (digital or analog) received from another device or die. In some embodiments, the EIC die 60 may include a circuit that provides Serializer/Deserializer (SerDes) functionality. In this manner, the EIC may act as a part of an I/O interface between optical signals and electrical signals.

It is appreciated that the processes as illustrated in FIGS. 20 through 24 are at wafer level, wherein a plurality of EIC dies 60 may be bonded to a plurality of photonic dies 20′ of the photonic wafer 20 in accordance with some embodiments.

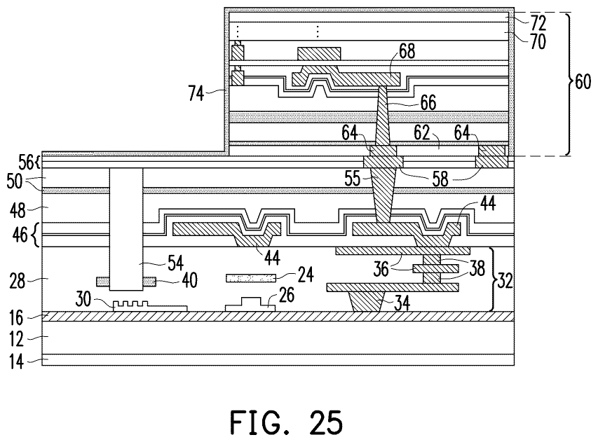

FIGS. 25 through 27 illustrate a gap-fill process in accordance with some embodiments, wherein the gaps between EIC dies 60 are filled to form dielectric regions (that encircle the EIC dies 60), which are also referred to as gap-fill regions.

Referring to FIG. 25, a dielectric barrier 74 is deposited. The deposition process includes a conformal deposition process such as ALD, CVD, or the like. The material of the dielectric barrier 74 is selected to have good adhesion ability on EIC dies 60. In some embodiments, the dielectric barrier 74 is formed of or comprises silicon nitride, silicon carbo-nitride, silicon oxynitride, silicon carbide, or the like, which material may be different from the material of the dielectric region 54 and the bond layer 56.

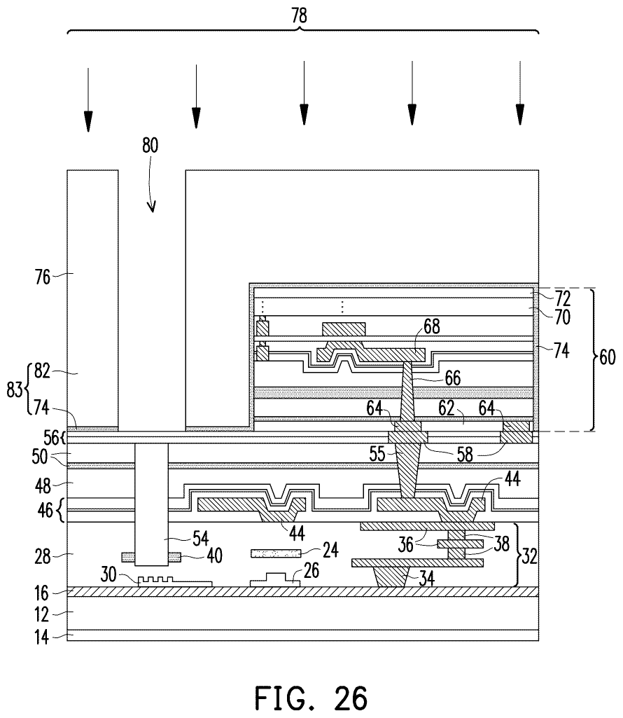

Referring to FIG. 26, an etching mask 76 is formed, which may be formed of a patterned photoresist. An etching process 78 is performed to etch and pattern the dielectric barrier 74, so that an opening 80 is formed, and the underlying bond layer 56 is exposed. The etching process 78 is performed using the bond layer 56 as an etch stop layer, so that the opening 80 extends into the dielectric barrier 74, and the bond layer 56 is exposed. In some embodiments, the entire opening 80 is directly over the bond layer 56, and no metal feature in the bond layer 56 is exposed to the opening 80. After the etching process 78, the etching mask 76 is removed, for example, through an ashing process. In some embodiments, as a result of the etching process 78, the bond layer 56 is etched through, and the underlying dielectric region 54 is exposed.

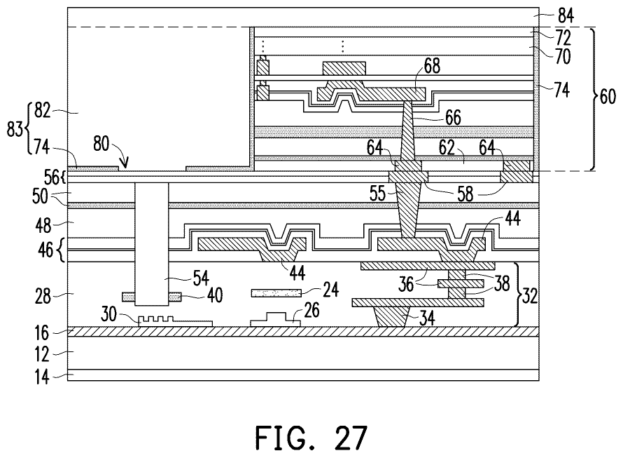

Referring to FIG. 27, a dielectric region 82, which is light-transparent, is formed. In some embodiments, the formation process may include depositing a dielectric material, and performing a planarization process such as a CMP process or a mechanical grinding process on the deposited dielectric material. The planarization process may use the dielectric barrier 74 or the semiconductor substrate 70 as a CMP stop layer. The dielectric material of the dielectric region 82 may comprise silicon oxide, silicon oxynitride, or the like. The dielectric material (such as silicon oxide) of the dielectric region 82 may also be the same as that of the bond layer 56, the dielectric region 54, and the portion of the dielectric layer 28 directly under the dielectric region 54. Throughout the description, the dielectric barrier 74 and the dielectric region 82 are collectively referred to as a gap-fill region 83.

Next, a bond layer 84 is formed through a deposition process. In some embodiments, the bond layer 84 is formed of or comprises silicon oxide, silicon oxynitride, or the like. In some embodiments, the bond layer 84 is formed of a same material as that of the dielectric region 82. The bond layer 84 and the dielectric region 82 may be, or may not be, distinguishable from each other, and may or may not include a distinguishable interface in between. Accordingly, the interface between the bond layer 84 and the dielectric region 82 is shown as being dashed to indicate that the interface may be or may not be distinguishable.

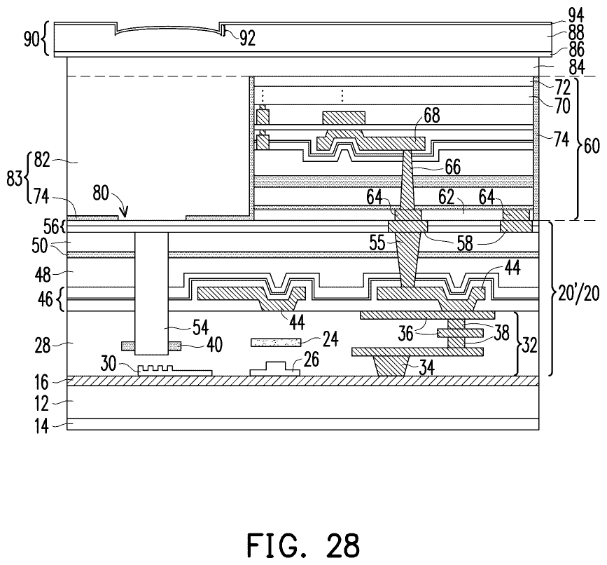

Referring to FIG. 28, a supporting substrate 90 (which may be a wafer) is bonded to the bond layer 84. In some embodiments, the supporting substrate 90 includes a bond layer 86, and a silicon substrate 88 attached to the bond layer 84. The bond layer 86 may be formed of or comprise a silicon-containing dielectric material such as silicon oxide, silicon oxynitride, silicon carbo-nitride, or the like. The bonding may include fusion bonding, with the bond layer 86 being bonded to the bond layer 84. In some embodiments, the material of the bond layer 86 is close to or the same as that of the bond layer 84 and the dielectric regions 82 and 54, for example, including silicon oxide.

In some embodiments, the supporting substrate 90 includes a micro lens 92, which is formed as a part of the silicon substrate 88, for example, through etching the silicon substrate 88. The supporting substrate 90 further includes a protection layer 94 formed on the silicon substrate 88. The protection layer 94 further includes a portion in the recess in the silicon substrate 88, in which the micro lens 92 is formed. The protection layer 94 may be a conformal layer formed of silicon oxide. The micro lens 92 is vertically aligned to the dielectric region 82, the opening 80 in the dielectric barrier layer 74, the dielectric region 54, and the grating coupler 30 in accordance with some embodiments.

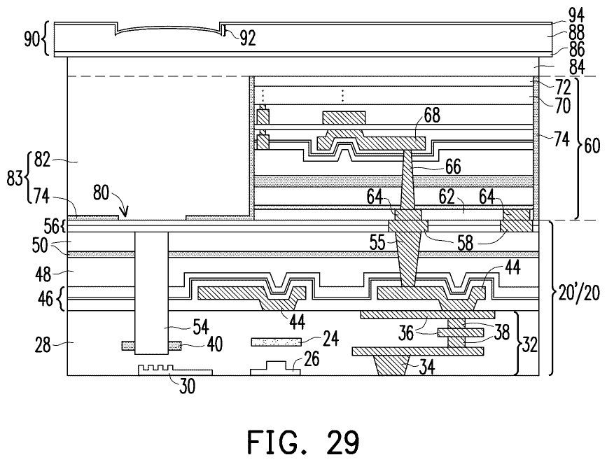

Next, the semiconductor substrate 12 and the dielectric layer 14 (and optionally the dielectric layer 16) are removed. The resulting structure is shown in FIG. 29. In some embodiments in which the photonic die 20′ includes active devices, the dielectric layer 14 and the semiconductor substrate 12 may remain. The removal process (if performed) may include a CMP process, a mechanical grinding process, or the like.

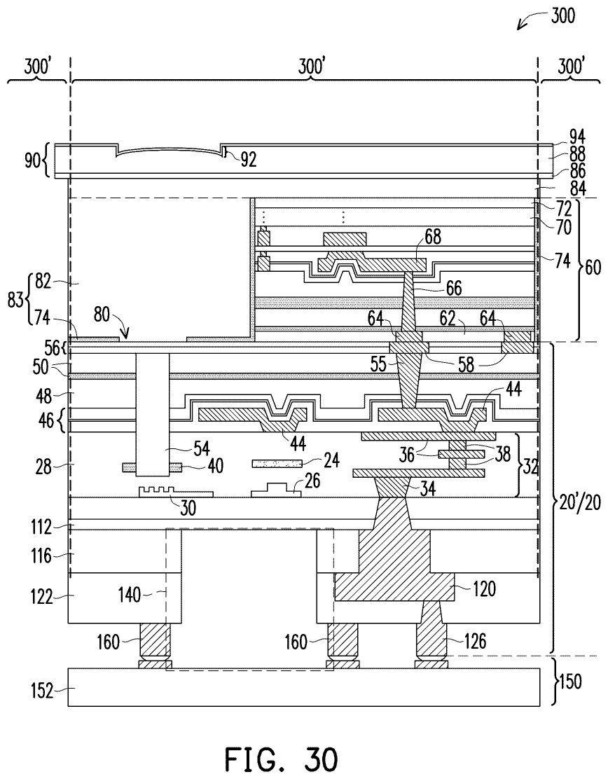

In subsequent processes, as shown in FIG. 30, the structure illustrated in FIGS. 1 through 19 are formed on the photonic die 20′. A reconstructed wafer 300 is thus formed.

In a subsequent process, a sawing process (also referred to as a singulation process) is performed to saw the reconstructed wafer 300 and to form a plurality of optical engines 300′, which are also referred to as an optical engine, packages, or photonic engines. The plurality of optical engines 300′ are identical, and each may include a photonic die 20s′, an EIC die 60, a supporting substrate 90, which is sawed from the wafer-level supporting substrate 90, and a substrate package 150. In some embodiments, the singulation process is performed before the substrate package 150 is attached.

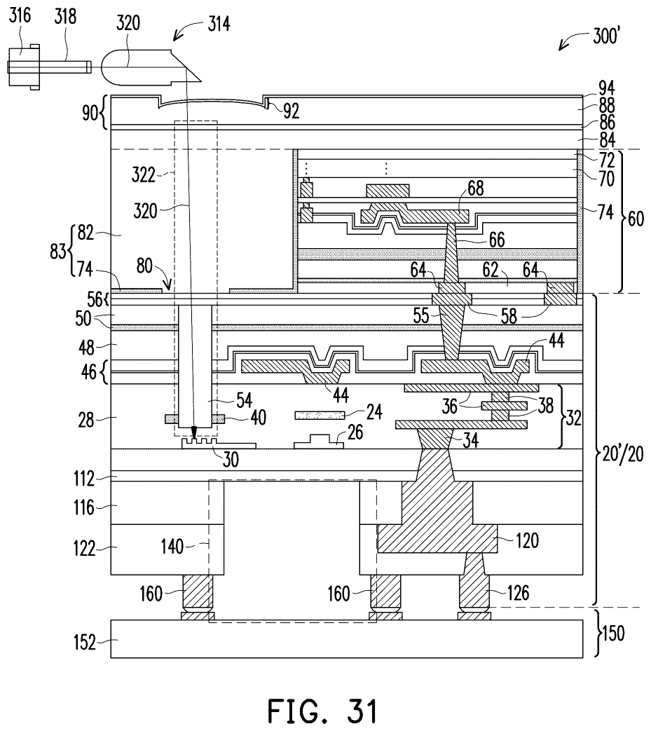

FIG. 31 illustrates the usage of the photonic engine 300′ in accordance with some embodiments. The photonic engine 300′ may be bonded to a package component (not shown) underlying and electrically connected to the photonic engine 300′. The underlying package component may include an interposer, a package substrate, a printed circuit board, or the like. A fiber assembly unit (FAU) 314 is attached to the underlying structure. An optical fiber 318 is attached to a fiber connector 316. A laser beam 320 may be projected out of the optical fiber 318, and reflected in the FAU 314. The laser beam 320 is reflected by a reflecting surface, and is projected to the micro lens 92. The laser beam 320 passes through an optical path 322 to reach the grating coupler 30, which conducts the optical signal into waveguides. The optical signals carried by the laser beam 320 are further processed by the photonic die 20′ and the EIC die 60. For example, the optical signals may be converted to electrical signals by the photonic die 20′, and the electrical signals are transferred to the EIC die 60. The photonic die 20 further includes the heater 24, the wavelength modulator 26, and adiabatic well 140 discussed above. In some embodiments, the heater 24 and wavelength modulator 26 are thermally coupled to allow for thermo-optical tuning of the optical carrier for resonance detuning. The adiabatic well 140 (also referred to as the metal-free region) helps to control and thermally isolate these components from other components in the package.

In some embodiments, as shown in FIG. 31, the laser beam 320 for carrying optical signals, after converged by the micro lens 92, passes through an optical path 322 to reach the grating coupler 30. The optical path 322 includes some portions of the bond layers 84 and 86, the dielectric region 82, the bond layer 56, the dielectric region 54, and the dielectric layer 28.

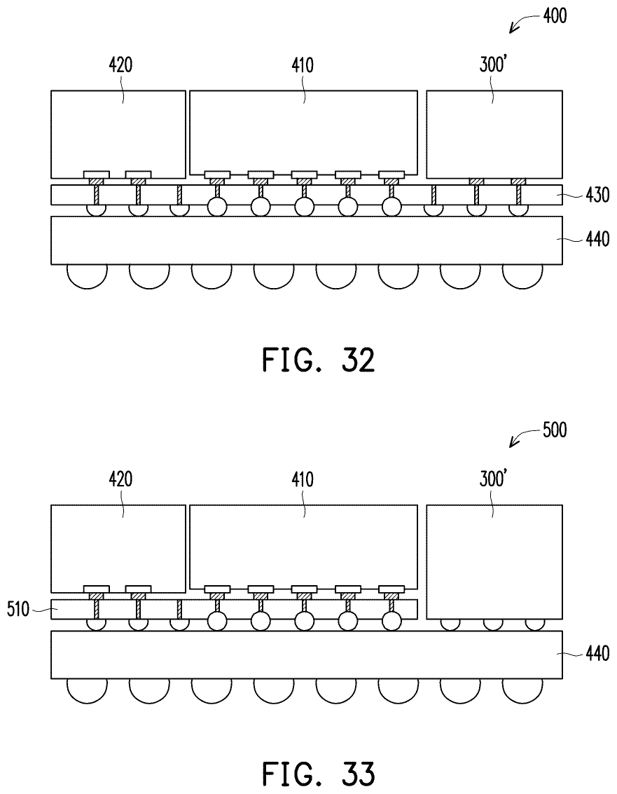

FIG. 32 illustrates a package structure 400 in accordance with some embodiments. The package structure 400 includes an optical engine 300′, which may be similar to that shown in FIGS. 30 and 31. The optical engine 300′ is mounted on an interposer 430, which provides interconnections between various components of the package.

Adjacent to the optical engine 300′ on the interposer 430 are a memory die 420 and a logic die 410. The memory die 420 may be a high bandwidth memory (HBM) die, and the logic die 410 may be a System-on-Chip (SoC) die, integrating various processing and control functions.

The interposer 430 is mounted on a substrate 440, which may be a package substrate. The substrate 440 provides additional routing layers and serves as an interface between the package components and the external circuitry.

This configuration allows for close integration of the optical engine 300′ with high-performance memory and logic components, enabling faster data transfer and processing. The use of an interposer 430 facilitates efficient interconnection between these diverse components, while the substrate 440 provides a stable base and external connectivity for the package structure 400.

FIG. 33 illustrates a package structure 500 in accordance with some embodiments. This structure is similar to the one shown in FIG. 32, but with the optical engine 300′ attached directly to the substrate 440.

In this configuration, the optical engine 300′ is mounted directly on the substrate 440. The logic die 410 and the memory die 420 are mounted on an interposer 510. The interposer 510 is mounted on the substrate 440, alongside the optical engine 300′. This arrangement differs from FIG. 32 in that the optical engine 300′ bypasses the interposer and connects directly to the substrate 440.

The substrate 440 serves may provide routing and external connections for the optical engine 300′, the interposer 510, and components mounted on the interposer 510. This configuration may offer advantages in terms of reduced signal path for the optical engine 300′, potentially improving its performance or integration flexibility.

Embodiments may achieve advantages. The present disclosure describes a thermal management approach through a packaging design. This design includes a photonic die that contains a wavelength modulator and a heating element. The heating element is thermally coupled to the modulator, which may allow for temperature control. The PIC die is integrated into the overall package structure in a specific manner.

The package includes an interconnect structure on top of the PIC die. This interconnect structure contains conductive features for electrical connections and a void or metal-free region. This void, also referred to as an “adiabatic well,” is positioned to overlap with the heating element and wavelength modulator when viewed from above. The void may form a thermal barrier, isolating the heat-sensitive components from the rest of the package.

To enhance the thermal management capabilities, the package may include additional features such as a Thermal Isolation Bump (TIB) and an intra-die seal ring. These structures may work together with the adiabatic well to provide thermal isolation. The TIB may surround the adiabatic well, potentially creating a buffer zone to limit heat spread to other parts of the package. The intra-die seal ring may help to contain potential degradation of passivation materials that could occur due to heat exposure.

This approach to thermal management in semiconductor packaging may offer several potential benefits. It may help reduce the risk of overheating and material degradation, which can be issues in high-performance photonic devices. By potentially maintaining more stable temperatures for the wavelength modulator and other optical components, the package design may contribute to consistent performance and potentially extend the lifespan of the device. This thermal management strategy may be implemented while maintaining the electrical connections necessary for the device's operation, as conductive connectors can still link the interconnect structure to other parts of the package.

In an embodiment, a semiconductor package may include a photonic integrated circuit (PIC) die having a wavelength modulator and a heating element thermally coupled to the wavelength modulator. The semiconductor package may also include an interconnect structure on the PIC die, where the interconnect structure may include a plurality of conductive features and a void. The void overlaps with the heating element and the wavelength modulator from a top view. The package may furthermore include a plurality of conductive connectors over the interconnect structure and electrically connected to the plurality of conductive features.

The described embodiments may also include one or more of the following features: the semiconductor package where the void may include an air gap; the semiconductor package where the air gap extends from a top surface of the PIC die to a bottom surface of the plurality of conductive connectors; the semiconductor package may include a thermal isolation structure surrounding the void; the semiconductor package where the thermal isolation structure may include a metal pillar and a solder region; the semiconductor package where the thermal isolation structure is configured to contain air within the void and provide a thermal buffer between the void and surrounding areas; the semiconductor package may include an electronic integrated circuit (EIC) die bonded to the interconnect structure.

In an embodiment, a method may include forming a photonic integrated circuit (PIC) die having a wavelength modulator and a heating element thermally coupled to the wavelength modulator. The method may also include forming an interconnect structure on the PIC die, where the interconnect structure may include a plurality of conductive features and a metal-free region without any of the plurality of conductive features therein. The metal-free region overlaps with the heating element and the wavelength modulator from a top view. The method may furthermore include forming a plurality of conductive connectors over the interconnect structure, where the conductive connectors are electrically connected to the plurality of conductive features.

The described embodiments may also include one or more of the following features: the method where forming the metal-free region may include forming an air gap extending from a top surface of the PIC die to a bottom surface of the plurality of conductive connectors; the method may include forming a thermal isolation structure surrounding the metal-free region; the method where forming the thermal isolation structure may include forming a metal pillar and a solder region; the method where the thermal isolation structure is configured to contain air within the metal-free region; the method may include bonding an electronic integrated circuit (EIC) die to the PIC die; the method may include forming optical components in the PIC die.

In an embodiment, a semiconductor device may include a photonic integrated circuit (PIC) die having an optical component. The semiconductor device may also include an interconnect structure on the PIC die, the interconnect structure having a dielectric layer and conductive features in the dielectric layer. The device may furthermore include an adiabatic well in the interconnect structure, the adiabatic well overlapping with the optical component from a top view. The device may in addition include a plurality of conductive connectors over the interconnect structure and electrically connected to the conductive features.

The described embodiments may also include one or more of the following features: the semiconductor device where the optical component may include a micro-ring modulator and a heater thermally coupled to the micro-ring modulator; the semiconductor device may include a thermal isolation structure surrounding the adiabatic well; the semiconductor device where the adiabatic well may include air; the semiconductor device where the adiabatic well may include thermal resist material; the semiconductor device may include an electronic integrated circuit (EIC) die bonded to the PIC die.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a photonic integrated circuit (PIC) die comprising a wavelength modulator and a heating element thermally coupled to the wavelength modulator;
an interconnect structure on the PIC die, wherein the interconnect structure comprises a plurality of conductive features and a void, the void overlapping with the heating element and the wavelength modulator from a top view; and
a plurality of conductive connectors over the interconnect structure and electrically connected to the plurality of conductive features.

2. The semiconductor package of claim 1, wherein the void comprises an air gap.

3. The semiconductor package of claim 2, wherein the air gap extends from a top surface of the PIC die to a bottom surface of the plurality of conductive connectors.

4. The semiconductor package of claim 1, further comprising a thermal isolation structure surrounding the void.

5. The semiconductor package of claim 4, wherein the thermal isolation structure comprises a metal pillar and a solder region.

6. The semiconductor package of claim 5, wherein the thermal isolation structure is configured to contain air within the void and provide a thermal buffer between the void and surrounding areas.

7. The semiconductor package of claim 1, further comprising an electronic integrated circuit (EIC) die bonded to the interconnect structure.

8. A method comprising:
forming a photonic integrated circuit (PIC) die comprising a wavelength modulator and a heating element thermally coupled to the wavelength modulator;
forming an interconnect structure on the PIC die, wherein the interconnect structure comprises a plurality of conductive features and a metal-free region without any of the plurality of conductive features therein, the metal-free region overlapping with the heating element and the wavelength modulator from a top view; and
forming a plurality of conductive connectors over the interconnect structure, wherein the conductive connectors are electrically connected to the plurality of conductive features.

9. The method of claim 8, wherein forming the metal-free region comprises forming an air gap extending from a top surface of the PIC die to a bottom surface of the plurality of conductive connectors.

10. The method of claim 9, further comprising forming a thermal isolation structure surrounding the metal-free region.

11. The method of claim 10, wherein forming the thermal isolation structure comprises forming a metal pillar and a solder region.

12. The method of claim 11, wherein the thermal isolation structure is configured to contain air within the metal-free region.

13. The method of claim 8, further comprising bonding an electronic integrated circuit (EIC) die to the PIC die.

14. The method of claim 13, further comprising forming optical components in the PIC die.

15. A semiconductor device, comprising:
a photonic integrated circuit (PIC) die comprising an optical component;
an interconnect structure on the PIC die, the interconnect structure comprising a dielectric layer and conductive features in the dielectric layer;
an adiabatic well in the interconnect structure, the adiabatic well overlapping with the optical component from a top view; and
a plurality of conductive connectors over the interconnect structure and electrically connected to the conductive features.

16. The semiconductor device of claim 15, wherein the optical component comprises a micro-ring modulator and a heater thermally coupled to the micro-ring modulator.

17. The semiconductor device of claim 16, further comprising a thermal isolation structure surrounding the adiabatic well.

18. The semiconductor device of claim 15, wherein the adiabatic well comprises air.

19. The semiconductor device of claim 15, wherein the adiabatic well comprises thermal resist material.

20. The semiconductor device of claim 15, further comprising an electronic integrated circuit (EIC) die bonded to the PIC die.
